(19) United States
(12) Patent Application Publication
(10) Pub. No.: US 2005/0266654 A1
(43) Pub. Date: Dec. 1, 2005

(54) Barrier to amorphization implant

(76) Inventors: Michael L. Hattendorf, Beaverton, OR (US); Peter J. Vandervoorn, Hillsboro, OR (US)

Correspondence Address: SCHWABE, WILLIAMSON & WYATT, P.C.;PACWEST CENTER, SUITE 1900, 1211 SW FIFTH AVENUE, PORTLAND, OR, 97204, US

(21) Appl. No.: 10/856,283

(22) Filed: May 27, 2004

(51) Int. Cl. H01L 21/76

(52) U.S. Cl. 438/424

(57) ABSTRACT

A method includes forming a first and a second semiconductor region which are joined at a semiconductor junction. The first and second semiconductor regions are truncated with an isolation trench, with an end of the semiconductor junction being disposed at the isolation trench. The isolation trench is at least partially filled with an insulation material. A salicide-blocking barrier is formed over a first surface portion of the first semiconductor region proximally disposed relative to the isolation trench. An amorphization implant is implanted in a second surface portion of the first semiconductor region distally disposed relative to the isolation trench. A salicide layer is formed in the amorphization implant.

### BACKGROUND OF THE INVENTION

1. Field of the Invention

The present invention relates to semiconductor structures, and in particular, to semiconductor structures using silicides.

2. Description of Related Art

FIG. 1 illustrates a pn semiconductor junction 10 of a semiconductor structure 12, which may be formed by Complementary MOS (CMOS) technology using trench isolation and pre-salicide blanket amorphization. For example, the pn junction 10 may be formed by the joining of a diffused region 14 and a well 16, with the diffused region 14 being formed in the well 16. The pn junction 10 terminates at one end in a trench 18, in which an insulating material 20 is deposited. The trench 18 and the insulating material 20 are used to electrically isolate the diffused region 14 from the well 16 at this end of the pn junction 10.

A salicide (self-aligned silicide) layer 22 may be formed over the diffused region 14 to reduce its effective electrical sheet resistance. During a salicide react fabrication stage, a noble or refractory metal forms compounds with the silicon of the diffused region 14. Prior to the react stage, an amorphization implant 24 may be implanted into the diffused region 14 to break the bonds of the silicon, to accelerate the salicide formation, and reduce the salicide sheet resistance.

The deposited insulating material 20 may not sufficiently cover up the pn junction 10 to protect it from amorphization damage due to the height of insulating material 20 being constrained by different processes and generally being decreased during a number of processes. Hence, a key concern is the location of the pn junction 10 relative to the height of the insulating material. At a trench/semiconductor boundary 26, amorphization defects may be spatially located at the pn junction 10 adjacent the isolation trench 18. More specifically, as illustrated in an electrically active defect region 28, the amorphization implant 24 may extend to and electrically connect with the well 16 in a region adjacent to the boundary 26 that traverses the pn junction 10. These defects may create an undesirable junction leakage between the diffused region 14 and the well 16.

It is a current practice in the prior art to adjust dopant profiles to move the pn junction 10 away from electrically active implant damage, i.e., move it lower in the well 16. If there was not this need for dopant profiles of the first and second semiconductor regions 44 and 46 to be adjusted to avoid the implant damage, then these dopant profiles instead may be used to optimize other aspects of performance, such as junction capacitance or electrical isolation.

FIG. 2 illustrates the prior art semiconductor structure 12 of FIG. 1 during one of its fabrication stages when a salicide-blocking film 30 is deposited on the surface of the wafer, which includes the surface of insulating material 20 in the trench 18 and the surface of the diffused region 14. The salicide-blocking film 30 shown in FIG. 2 is used to block salicidization of poly resistors (not shown) of the semiconductor structure 12. The salicide-blocking film 30 is etched away from the insulating material 20, pn junction 10, and diffused region 14 prior to forming of the amorphization implant 24 and the salicide layer 22 shown in FIG. 1, such etching being undertaken to allow amophization and salicidization of the diffused region 14.

It is known in the prior art to use an oxide spacer adjacent to a polysilicon gate to prevent silicide formation on the side of the gate which could cause a short between the gate and the diffusions. The spacer is formed by first coating the surface with an oxide and/or nitride or other dielectric film, followed by a reactive-ion edging stage. The oxide along the edge of the gate is thicker than over other regions, and some oxide is left on the side of the gate at the point when the oxide is completely removed from the source and drain regions and the top of the gate.

### BRIEF DESCRIPTION OF THE DRAWINGS

FIG. 1 is a cross-sectional view of a prior art semiconductor structure formed in a wafer by a prior art CMOS process using trench isolation and pre-salicide amorphization.

FIG. 2 is a cross-sectional view of the prior art semiconductor structure of FIG. 1 during a fabrication stage wherein a salicide-blocking film has been deposited.

FIG. 3 is a cross-sectional view of a semiconductor structure formed in a wafer, in accordance with one embodiment of the present invention.

FIG. 4 shows a flow chart of a first fabrication flow process, according to one method of the present invention, for fabricating the semiconductor structure of FIG. 3.

FIG. 5 is a cross-sectional view of the semiconductor structure of FIG. 3 before a salicide-blocking film deposition stage of the first fabrication process of FIG. 4.

FIG. 6 is a cross-sectional view of the semiconductor structure of FIG. 3 after the salicide-blocking film deposition stage of the first fabrication process of FIG. 4.

FIG. 7 is a cross-sectional view of the semiconductor structure of FIG. 3 after a patterned photoresist formation stage of the first fabrication process of FIG. 4.

FIG. 8 is a cross-sectional view of the semiconductor structure of FIG. 3 after an oxide etching and photoresist removal stage of the first fabrication process of FIG. 4.

FIG. 9 is a cross-sectional view of the semiconductor structure of FIG. 3 after an amorphization implant stage of the first fabrication process of FIG. 4.

FIG. 10 is a cross-sectional view of the semiconductor structure of FIG. 3 after a salicide formation stage of the first fabrication process of FIG. 4.

FIG. 11 is a cross-sectional view of the semiconductor structure of FIG. 3 after a metal etching stage of the first fabrication process of FIG. 4.

FIG. 12 is a cross-sectional, fragmented view of another semiconductor structure formed in a wafer, in accordance with another embodiment of the present invention.

FIG. 13 shows a flow chart of a second fabrication flow process, according to another method of the present invention, for fabricating the semiconductor structure of FIG. 12.

FIG. 14 is a block diagram of a system including a semiconductor package having the semiconductor structure of FIG. 3 according to one embodiment of the invention or the semiconductor structure of FIG. 12 according to another embodiment of the present invention.

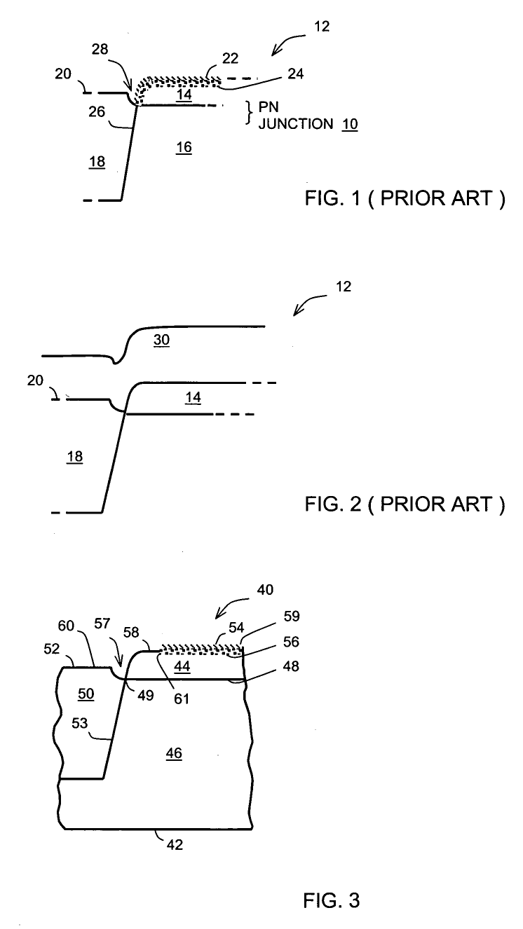

### DETAILED DESCRIPTION OF ILLUSTRATIVE EMBODIMENTS

In the following description, for purposes of explanation, numerous details are set forth in order to provide a thorough understanding of the disclosed embodiments of the present invention. However, it will be apparent to one skilled in the art that these specific details are not required in order to practice the disclosed embodiments of the present invention. In other instances, well-known electrical structures and circuits are shown in schematic, fragmented form in order not to obscure the disclosed embodiments of the present invention.

FIG. 3 illustrates a semiconductor structure 40 formed in a wafer 42. The semiconductor structure 40 includes first and second semiconductor regions 44 and 46, one region containing a p-type semiconductor material and the other region containing an n-type semiconductor material. More specifically, the first semiconductor region 44 may be the p-type semiconductor material and the second semiconductor region 46 may be the n-type material or vice versa. A pn junction 48 (i.e., semiconductor junction) is formed at the location where the semiconductor regions 44 and 46 join. The pn junction 48 is terminated at one end 49 on an isolation trench 50 having an insulating material 52 therein. The isolation trench 50 truncates the first and second semiconductor regions 44 and 46 so as to electrically isolate the first semiconductor region 44 on one side of the pn junction 48 from the second semiconductor region 46 on the other side of the pn junction 48. The trench 50 and the two semiconductor regions 44 and 46 join together to form a trench/semiconductor boundary 53, with one end of the pn junction 48 abutting against and terminating at the boundary 53.

In a salicide react stage during fabrication methods described hereinafter, a salicide layer 54 is formed in the first semiconductor region 44. The salicide layer 54 may be used to reduce the effective electrical sheet resistance of the first semiconductor region 44. In a more complex semiconductor structure 40, such as a MOS transistor, the salicide layer 54 also may be used to reduce the sheet resistance of other components, such as a gate electrode (not shown). Prior to salicide react stage, an amorphization implant 56 is implanted into the first semiconductor region 44 to break the bonds of the silicon so as to assist in forming the salicide layer 54.

In the fabrication methods described hereinafter, prior to the forming the salicide layer 54 and the amorphization implant 56, a salicide-blocking barrier (shown in FIGS. 8-11 to be discussed hereinafter) is formed over the trench/semiconductor boundary 53 to provide a protected region 57 which is not exposed to the amorphization implant 56 or the salicide layer 54. More specifically, the surface of the first semiconductor region 44 may be defined to have two parts: a first surface portion 58 proximally disposed relative to the isolation trench 50 and a second surface portion 59 distally disposed relative to the isolation trench 50, with the first surface portion 58 being adjacent to the trench 50 and the boundary 53. The salicide-blocking barrier at least extends over the first surface portion 58 of the first semiconductor region 44. Moreover, the salicide blocking barrier may not only extend over the first surface portion 58, but it may traverse the boundary 53 and extend over at least a portion of or all of a surface 60 of the insulating material 52 adjacent to the boundary 53. In other words, the salicide-blocking barrier may be formed on both sides of the boundary 53 so as to further reduce amorphization damage in the region 57. The amorphization implant 56, which has a proximal and a distal end relative to the isolation trench 50, extends over the unprotected second surface portion 59 of the first semiconductor region 44. Consequently, as a result of using this salicide-blocking barrier, the proximal end 61 of the amorphization implant 56 is disposed in spaced-apart relationship both to the boundary 53 and the end 49 (i.e., junction end) of the pn junction 48, which intersects and terminates at the boundary 53.

In summary, use of a physical barrier, in the form of the salicide-blocking barrier to be described hereinafter, blocks electrically active amorphization implant damage from pn junction 48 abutting the trench/semiconductor boundary 53. This in turn may improve the electrical performance of the semiconductor structure 40, which may include one or more pn junctions 48 using trench isolation, such as the isolation trench 50. More specifically, leaky and/or non-ideal diode characteristics caused by the amorphization implant damage in the pn junction 48 at trench-semiconductor boundary 53 may be reduced. By removing concerns about electrically active implant damage, the fabrication methods described hereinafter may not require dopant profiles of the first and second semiconductor regions 44 and 46 to be adjusted to avoid amorphization implant damage as undertaken in the prior art, but instead these dopant profiles may be used to optimize other aspects of performance, such as junction capacitance or electrical isolation.

The semiconductor structure 40 may take any number of forms as long as it has at least one pn junction 44 terminating in an isolation trench 50 and uses pre-salicide amorphization. In one embodiment, which illustrates a simple example, the semiconductor structure 40 may be a two-terminal, pn-junction MOS diode, as shown in FIG. 3. This diode example is selected because each MOS transistor implicitly contains a number of reverse-biased diodes. In one embodiment of the semiconductor structure 40, the first semiconductor region 44 may be a diffused region and the second semiconductor region 46 may be a well (as shown in FIG. 3) or a substrate. More specifically, in one embodiment, the first semiconductor region 44 may be a diffused region of a p+ (heavily doped p-type) material and the second semiconductor region 46 may be an n-well. In another embodiment, the first semiconductor region 44 may be a diffused region of an n+ (heavily doped n-type) material and the second semiconductor region 46 may be a p-well. In another embodiment, the second semiconductor region 46 may be a substrate, either an n-substrate or a p-substrate, depending upon whether the first semiconductor region 44 is a p-type or n-type, respectively. In another embodiment, the semiconductor structure 40 may be implemented using silicon-on-Insulator (SOI) technology, wherein the semiconductor structure 40 may be constructed in a thin layer of silicon deposited on top of a thick layer of insulating silicon dioxide.

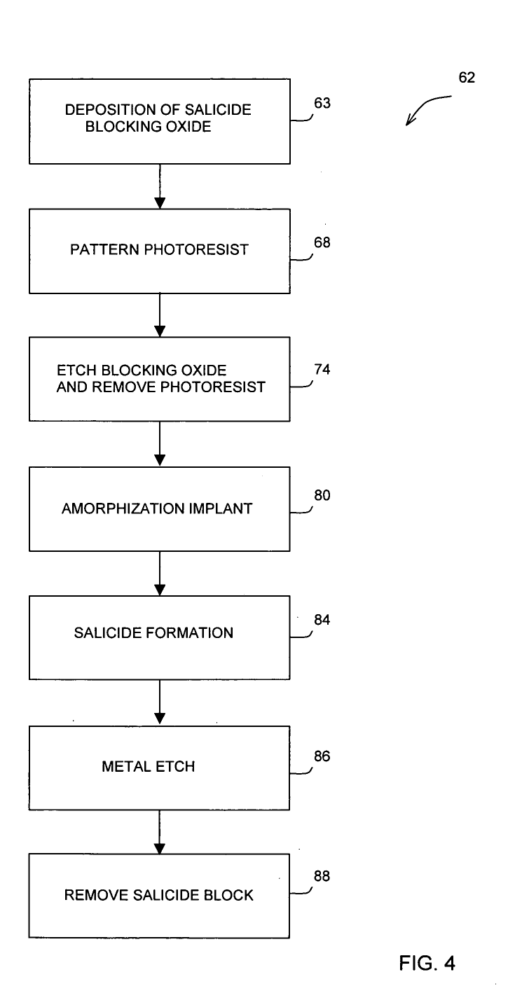

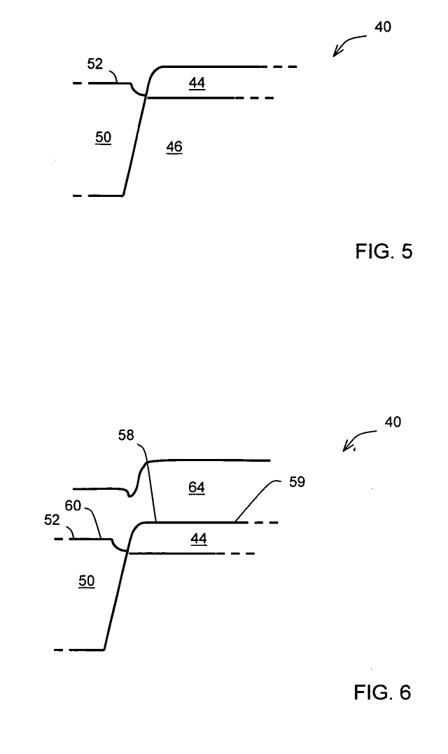

A first CMOS fabrication method 62 for fabricating the semiconductor structure 40 of FIG. 3 is illustrated in a flow chart shown in FIG. 4. Additionally, the fabrication of the semiconductor structure 40 is illustrated in FIGS. 5-11 as it passes through the fabrication stages of the first fabrication method 62. Generally, in the fabrication method 62, a mask or lithographic layer may be used to pattern a photoresist layer, which in turn may be used to etch a salicide-blocking film so as to form the previously-mentioned salicide-blocking barrier for covering the protected region 57 from exposure to the amorphization damage. In one embodiment, the lithographic layer utilized for this purpose may be a lithographic layer already incorporated into the fabrication process for the semiconductor structure 40, such as a lithographic layer used in the formation of polysilicon (poly) resistors (not shown). In this embodiment, the lithographic layer may be modified to provide a window needed to form the salicide-blocking barrier.

Referring to FIGS. 4 and 5, the semiconductor structure 40, formed in the wafer, is shown in FIG. 5 as it exists prior to starting the first fabrication method 62 of FIG. 4. The first and second semiconductor regions 44 and 46 and the isolation trench have been formed. The isolation trench 50 has been filled with the insulating material 52. In one embodiment, the insulating material 52 may be silicon dioxide.

Referring to FIGS. 4 and 6, at a deposition stage 63 of the first fabrication method 62, the salicide-blocking film 64, in the form of a salicide-blocking oxide layer, may be deposited over the surface 60 of the insulating material 52 contained in the isolation trench 50 and over the entire surface of the first semiconductor region 44, including the first and second surface portions 58 and 59.

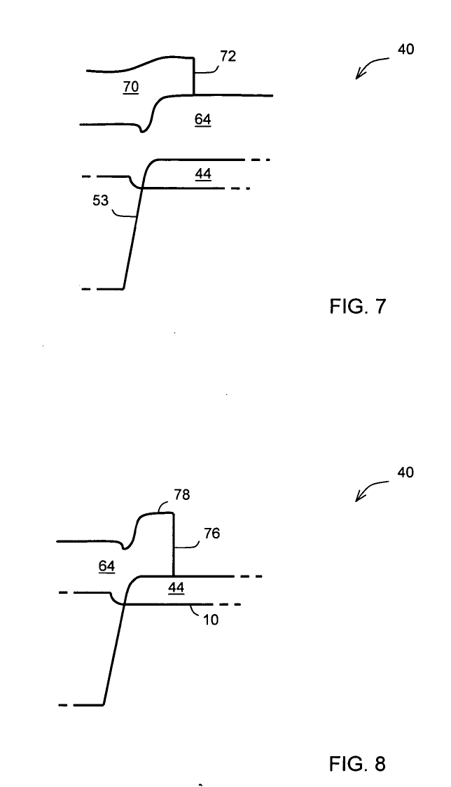

Referring to FIGS. 4 and 7, at a photoresist patterning stage 68 of the first fabrication method 62, a photoresist layer may be patterned by the lithographic layer, leaving a photoresist layer portion 70 traversing the trench/semiconductor boundary 53. The photoresist layer portion 70 terminates at a photoresist end 72. More specifically, the photoresist patterning stage 68 may be broken down the following phases. In a spin phase, the photoresist layer may be evenly applied by spinning the wafer. In an exposure phase, the previously-described lithographic layer containing the desired pattern for the salicide-blocking barrier may be bought in close proximity with the wafer and the combination wafer and lithographic layer may be exposed to ultraviolet light. In a development phase, unexposed photoresist (assuming negative photoresist) may be removed and the wafer may be soft baked to harden the remaining photoresist. In one embodiment, the lithographic layer used is a modified, pre-existing lithographic previously used to form gate electrodes in the prior art structures. In another embodiment, a negative photoresist may be used.

Referring to FIGS. 4, 7 and 8, at an etching and removal stage 74 of the first fabrication method 62, the salicide-blocking film 64 is etched so that it terminates at a film end 76, thereby forming a salicide-blocking barrier 78. In other words, the salicide-blocking film 64 past the film end 76 has been removed because it was not covered by the photoresist layer portion 70 shown in FIG. 7 during etching. Thereafter, as shown in FIG. 8, the photoresist layer portion 70 shown in FIG. 7 may be removed, although its removal may be delayed until later in the fabrication method 62.

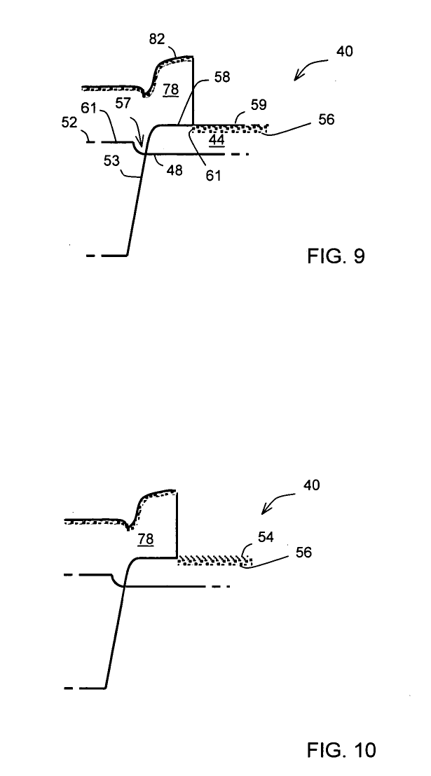

Referring to FIGS. 4 and 9, at an amorphization implant stage 80 of the first fabrication method 62, the amorphization implant 56 is implanted on the second surface portion 59 of the first semiconductor region 44 that is not covered by the salicide-blocking barrier 78. However, there is no amorphization implant under the salicide-blocking barrier 78 at the boundary 53, which includes the surface 60 of the insulating material 52 and the first surface portion 58 of the first semiconductor region 44. A second amorphization implant area 82 is formed on the salicide-blocking barrier 78, but it may be removed when the salicide-blocking barrier 78 is removed in a later stage of the fabrication method 62. Hence, the end 61 of the amorphization implant 56 is disposed in spaced-apart relationship both to the boundary 53 and the location at which the pn junction 48 intersects and terminates on the boundary 53. Salicide formation, to be discussed hereinafter, may be enhanced by the amorphization implant 56. Producing the amorphization implant 56 in the first semiconductor region 44 may be performed through ion implantation. The depth to which the amorphization implant 56 may be determined and controlled by selection of the atomic weight of the ion species used for implantation, the implantation energy, and the dosage of ions implanted in the silicon body. For example, the second surface portion 59 of the first semiconductor region 44 may be bombarded by arsenic ions. The arsenic ions may damage the internal crystal structure of the silicon of the first semiconductor region 44 so that a layer of amorphous silicon is formed. In summary, the salicide-blocking barrier 78 acts as a physical barrier that prevents electrically active amorphization in the protected region 57.

Referring to FIGS. 4 and 10, at a salicide formation stage 84 of the first fabrication method 62, the salicide layer 54 is formed. The salicide formation stage 84 may be subdivided into a number of phases. In a metal deposit phase, a metal layer is placed in contact with the amorphization implant 56. Positioning the metal layer on the amorphous region may be performed by sputtering, evaporating or chemical vapor deposition. The metal may be one of a number of metals, such as titanium, cobalt and nickel. In a react phase, thermal treatment for extended periods of time is used to react the metal with the amorphous silicon to form the salicide layer 54. For example, in one embodiment the metal layer may be irradiated with light to diffuse metal into the amorphization implant 56 to form an alloy region of salicide composition from the amorphous region of the amorphization implant 56. Salicidization (i.e., salicide formation) may occur only in the limited portion of the first semiconductor region 44 that is rendered amorphous through ion implantation, i.e., the amorphization implant 56. The irradiation of the metal layer may be accomplished with pulsed laser light with a fluence (surface laser energy density) sufficient to render the amorphous region of the amorphization implant 56 molten. By diffusion of metal from the metal layer caused by the heating of the irradiation, the region of the amorphization implant 56 becomes an alloy region.

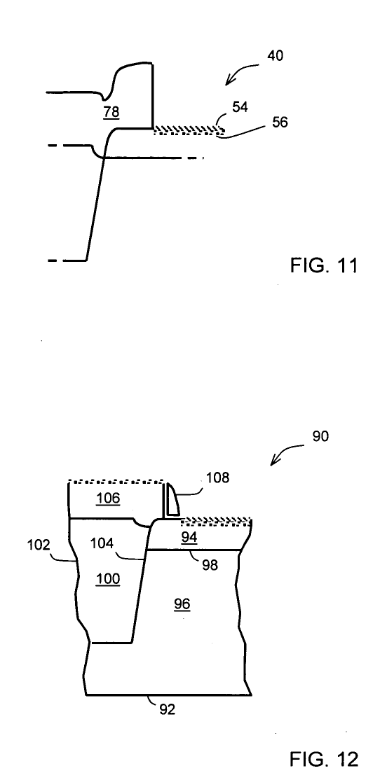

Referring to FIGS. 4 and 11, at a metal etch or strip stage 86 of the first fabrication method 62, unreacted metal is removed leaving the alloy, i.e., the salicide layer 54. In one embodiment, in an anneal phase, a higher salicide resistivity of the salicide layer 54 may be changed into a lower silicide resistivity. The salicide layer 54 is a self-aligned silicide layer, i.e., automatically self-aligned with the first semiconductor region 44 and, if any, the gate electrode. For example, when the semiconductor structure 40 comprises a MOS transistor, after the unreacted metal has been removed by this selective edging stage 86 (does not attack the silicide), the resulting silicide is automatically self aligned to the gate and source-drain regions; hence, self-aligned silicides are called salicides.

Referring to FIGS. 4 and 3, at a removal stage 88 of the first fabrication method 62, the salicide-blocking barrier 78 shown in FIG. 11 is removed, leaving the semiconductor structure 40 in completed form as shown in FIG. 3.

Referring to FIG. 12, there is shown a semiconductor structure 90 in a wafer 92 (wafer partially shown), according to a second embodiment of the present invention, which is manufactured by a second CMOS fabrication method, according to another method of the present invention. The semiconductor structure 90 includes first and second semiconductor regions 94 and 96, one region containing a p-type semiconductor material and the other region containing an n-type semiconductor material. More specifically, the first semiconductor region 94 may be the p-type semiconductor material and the second semiconductor region 96 may be the n-type material or vice versa. A pn junction 98 (i.e., semiconductor junction) is formed where the semiconductor regions 94 and 96 join. The pn junction 98 is terminated at one end with an isolation trench 100 filed with an insulating material 102. The trench isolation trench 100 and the insulating material 102 are used to electrically isolate the first semiconductor region 94 on one side of the pn junction 98 from the second semiconductor region 96 on the other side of the pn junction 98. The trench 100 and the semiconductor regions 94 and 96 join together to form a trench/semiconductor boundary 104, with one end of the pn junction 98 abutting against the trench/semiconductor boundary 104.

A patterned, deposited material may be used in the second fabrication method to construct a gate electrode (not shown) in the semiconductor structure 90. The patterned, deposited material may comprise a gate-forming material such as a poly-crystalline silicon (polysilicon) or a metal. In the second fabrication method, the patterned, deposited material may also be used to form a salicide-blocking barrier 106 to block amorphization implant damage in the pn junction 98. The salicide-blocking barrier 106 may be deposited and patterned at the same as the gate electrode is patterned and deposited. In one embodiment, a sidewall oxide spacer 108 may be formed adjacent to salicide-blocking barrier 106. Although not required, the oxide spacer 108 may be combined with the salicide-blocking barrier 106 to supplement the area of the first semiconductor 94 which is blocked from exposure to the amorphization and salicidization processes.

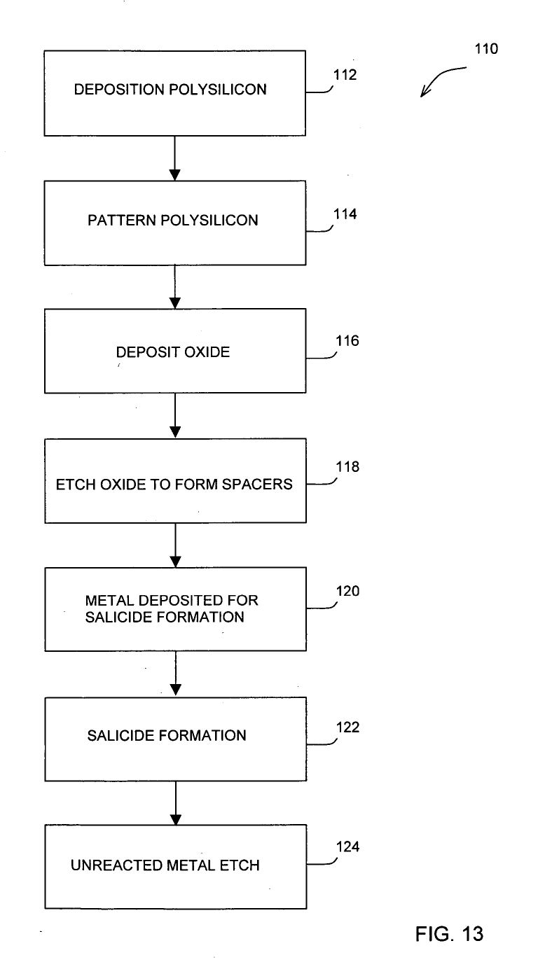

The semiconductor structure 90 may have a gate electrode (not shown). For the purposes of illustration, the gate electrode is shown formed of polysilicon. A flow chart of the second fabrication method 110 for fabrication the semiconductor structure 90 in the wafer 92 is shown in FIG. 13. Referring to FIGS. 12 and 13, at a polysilicon deposition stage 112, the polysilicon may be deposited over the MOS structures, including over the trench 100. Using photolithography, at a polysilicon patterning stage 114, the polysilicon is patterned to form gate electrodes and to form the salicide-blocking barrier 106 disposed over the boundary 104. After the polysilicon definition, at an oxide deposition stage 116, an oxide may be deposited over the MOS structures of the semiconductor structure 90. At an oxide etching stage 118, reactive-ion etching may be used to leave sidewall oxide spacers, such as the sidewall oxide spacer 108.

Once formed, the salicide-blocking barrier 106 of FIG. 12 is used in the same manner as the salicide-blocking barrier 78 of FIG. 9 is used in the amorphization implant, salicide formation, and metal etch stages of FIG. 4. Hence, these stages are only briefly described hereinafter. Referring back to FIG. 13, at a metal deposition stage 120, the metal is deposited over the structure. At a salicide formation or react stage 122, the metal is heated to form the suicides. At a metal etching stage 124, unreacted metal is etched away, leaving silicide automatically aligned with gate and/or source-drain regions, including the boundary 104. However, in the second fabrication method 110, the salicide-blocking barrier 106 may be left at semiconductor/trench boundary 104 as part of a normal gate electrode formation; hence, there is no need for an equivalent stage to the barrier removal stage 88 of FIG. 4.

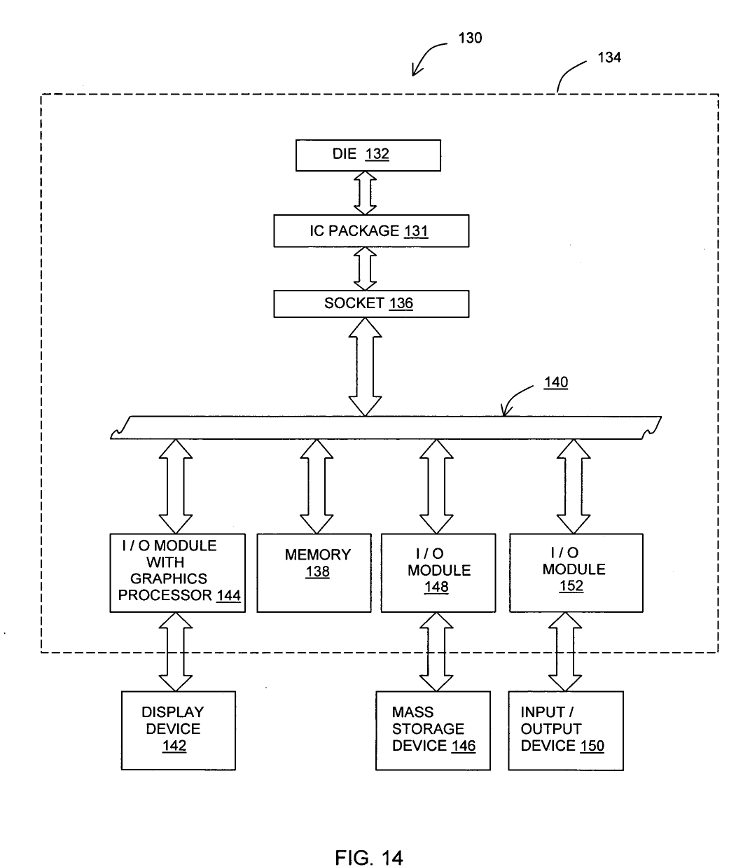

Referring to FIG. 14, there is illustrated a system 130, which is one of many possible systems in which a semiconductor package 131 may be used, such semiconductor package 131 including an integrated circuit (IC) die 132 having the semiconductor structure 40 of FIG. 3 or the semiconductor structure 90 of FIG. 12. The semiconductor package 131 may be mounted on a substrate or printed circuit board (PCB) 134 via a socket 136. The IC die 132 of the semiconductor package 131 may be a processor and the PCB 134 may be a motherboard. However, in other systems the semiconductor package 131 may be directly coupled to the PCB 134 (eliminating the socket 136 which allows the semiconductor package 131 to be removable). In addition to the socket 136 and the semiconductor package 131, the PCB 134 may have mounted thereon a main memory 138 and a plurality of input/output (I/O) modules for external devices or external buses, all coupled to each other by a bus system 140 on the PCB 134. More specifically, the system 130 may include a display device 142 coupled to the bus system 140 by way of an I/O module 144, with the I/O module 144 having a graphical processor and a memory. The I/O module 144 may be mounted on the PCB 134 as shown in FIG. 14 or may be mounted on a separate expansion board. The system 130 may further include a mass storage device 146 coupled to the bus system 140 via an I/O module 148. Another I/O device 150 may be coupled to the bus system 140 via a network interface I/O module 152. Additional I/O modules may be included for other external or peripheral devices or external buses.

Examples of the main memory 138 include, but are not limited to, static random access memory (SRAM) and dynamic random access memory (DRAM). The memory 138 may include an additional cache memory. Examples of the mass storage device 146 include, but are not limited to, a hard disk drive, a compact disk drive (CD), a digital versatile disk driver (DVD), a floppy diskette, a tape system and so forth. Examples of the input/output devices 150 may include, but are not limited to, devices suitable for communication with a computer user (e.g., a keyboard, cursor control devices, microphone, a voice recognition device, a display, a printer, speakers, and a scanner) and devices suitable for communications with remote devices over communication networks (e.g., Ethernet interface device, analog and digital modems, ISDN terminal adapters, and frame relay devices). In some cases, these communications devices may also be mounted on the PCB 134. Examples of the bus system 140 include, but are not limited to, a peripheral control interface (PCI) bus, and Industry Standard Architecture (ISA) bus, and so forth. The bus system 140 may be implemented as a single bus or as a combination of buses (e.g., system bus with expansion buses). Depending upon the external device, I/O modules internal interfaces may use programmed I/O, interrupt-driven I/O, or direct memory access (DMA) techniques for communications over the bus system 140. Depending upon the external device, external interfaces of the I/O modules may provide to the external device(s) a point-to point parallel interface (e.g., Small Computer System Interface—SCSI) or point-to-point serial interface (e.g., EIA-232) or a multipoint serial interface (e.g., FireWire). Examples of the IC die 132 may include any type of computational circuit such as, but not limited to, a microprocessor, a microcontroller, a complex instruction set computing (CISC) microprocessor, a reduced instruction set computing (RISC) microprocessor, a very long instruction word (VLIW) microprocessor, a graphics processor, a digital signal processor (DSP), or any other type of processor or processing circuit.

In various embodiments, the system 130 may be a wireless mobile or cellular phone, a pager, a portable phone, a one-way or two-way radio, a personal digital assistant, a pocket PC, a tablet PC, a notebook PC, a desktop computer, a set-top box, an entertainment unit, a DVD player, a server, a medical device, an internet appliance and so forth.

Although specific embodiments have been illustrated and described herein, it will be appreciated by those of ordinary skill in the art that any arrangement which is calculated to achieve the same purpose may be substituted for the specific embodiment shown. This application is intended to cover any adaptations or variations of the present invention. Therefore, it is manifestly intended that this invention be limited only by the claims and the equivalents thereof.

1. A method, comprising:
forming a first and a second semiconductor region joined at a semiconductor junction;
truncating the first and second semiconductor regions with an isolation trench so that an end of the semiconductor junction is disposed at the isolation trench;
at least partially filling the isolation trench with an insulation material;
forming a salicide-blocking barrier over a first surface portion of the first semiconductor region proximally disposed relative to the isolation trench;
implanting an amorphization implant in a second surface portion of the first semiconductor region distally disposed relative to the isolation; and
forming a salicide layer in the amorphization implant.

2. The method according to claim 1, wherein the forming of the salicide-blocking barrier further includes forming the salicide-blocking barrier over at least a portion of a surface of the insulating material disposed adjacent to the first semiconductor region.

3. The method according to claim 1, wherein the truncating of the first and second semiconductor regions with the isolation trench includes forming a boundary between the isolation trench and the semiconductor regions with the end of the semiconductor junction being disposed at the boundary and wherein the depositing of the salicide-blocking barrier includes forming the salicide-blocking barrier on both sides of the boundary.

4. The method according to claim 2, wherein the forming of salicide-blocking barrier includes depositing an oxide layer over the first semiconductor region and the insulating material and patterning the oxide layer to form the salicide-blocking barrier.

5. The method according to claim 4, wherein the patterning of the oxide layer includes depositing a photoresist layer over the first semiconductor region and the insulating material; patterning the photoresist layer with a lithographic layer; etching the oxide layer using the photoresist layer; and removing the photoresist layer.

6. The method according to claim 5, further comprising removing the salicide-blocking barrier after forming the salicide layer.

7. The method according to claim 6, further comprising using the lithographic layer in the formation of at least one polysilicon resistor.

8. The method according to claim 2, wherein the forming of the salicide-blocking barrier includes depositing a gate-forming material over the first semiconductor region and the insulating material and patterning the gate-forming material to form the salicide-blocking barrier.

9. The method according to claim 8, wherein the gate-forming material is a selected one of a polysilicon and a metal.

10. The method according to claim 9, further comprising depositing an oxide layer on the gate-forming material and etching the oxide layer to form an oxide spacer adjacent to the salicide-blocking barrier.

11. The method according to claim 10, further comprising using the gate-forming material in a gate electrode formation.

12. The method according to claim 2, wherein the first semiconductor region is formed of a selected one of a p-type and an n-type semiconductor material and the second semiconductor region is formed from the other one of the p-type and the n-type semiconductor materials.

13. The method according to claim 12, wherein the second semiconductor region is a semiconductor well and the first semiconductor region is a diffused area formed in the semiconductor well.

14. A method, comprising:
forming a first and a second semiconductor region joined at a semiconductor junction;
truncating the first and second semiconductor regions with an isolation trench so that an end of the semiconductor junction is disposed at the isolation trench;
at least partially filling the isolation trench with an insulation material;
depositing an oxide layer over the first semiconductor region and the insulating material;
patterning the oxide layer to form a salicide-blocking barrier over a first surface portion of the first semiconductor region proximally disposed relative to the isolation trench and over at least a portion of a surface of the insulating material disposed adjacent to the first semiconductor region;
implanting an amorphization implant in a second surface portion of the first semiconductor region distally disposed relative to the isolation trench; and
forming a salicide layer in the amorphization implant.

15. The method according to claim 14, wherein the patterning of the oxide layer includes depositing a photoresist layer over the first semiconductor region and the insulating material; patterning the photoresist layer with a lithographic layer; etching the oxide layer using the photoresist layer; and removing the photoresist layer.

16. The method according to claim 15, further comprising removing the salicide-blocking barrier after forming the salicide layer.

17. The method according to claim 16, further comprising using the lithographic layer in the formation of at least one polysilicon resistor.

18. A method, comprising:
forming a first and a second semiconductor region joined at a semiconductor junction;
truncating the first and second semiconductor regions with an isolation trench so that an end of the semiconductor junction disposed at the isolation trench;
at least partially filling the isolation trench with an insulation material;
depositing a gate-forming material over the first semiconductor region and the insulating material;
patterning the gate-forming material to form a salicide-blocking barrier over a first surface portion of the first semiconductor region proximally disposed relative to the isolation trench and over at least a portion of a surface of the insulating material disposed adjacent to the first semiconductor region;
implanting an amorphization implant in a second surface portion of the first semiconductor region distally disposed relative to the isolation trench; and
forming a salicide layer in the amorphization implant.

19. The method according to claim 18, wherein the gate-forming material is a selected one of a polysilicon and a metal.

20. The method according to claim 19, further comprising depositing an oxide layer on the gate-forming material and etching the oxide layer to form an oxide spacer adjacent to the salicide-blocking barrier.

21. The method according to claim 20, further comprising using the gate-forming material in a gate electrode formation.

22. An apparatus, comprising:
a first semiconductor region;
a second semiconductor region joined to the first semiconductor region to form a semiconductor junction;
an isolation trench at least partially filled with an insulating material and disposed in a truncating relationship with the first and second semiconductor regions, with the semiconductor junction terminating at the isolation trench so as to define a junction end of the semiconductor junction; and
an amorphization implant being formed in the first semiconductor region and having a proximal and a distal implant end relative to the junction end of the semiconductor junction, the proximal implant end being disposed in spaced-relationship to the junction end.

23. The apparatus according to claim 22, further comprising:
a boundary defined between the isolation trench and the first and second semiconductor regions, with the junction end of the semiconductor junction terminating at the boundary; and
a salicide-blocking barrier formed on a first portion of the first semiconductor region located adjacent to the boundary.

24. The apparatus according to claim 23, wherein the salicide-blocking barrier extends at least from the boundary to the proximal implant end.

25. The apparatus according to claim 23, wherein the salicide-blocking barrier is formed on at least a portion of the insulating material adjacent to the boundary.

26. The apparatus according to claim 25, further comprising:
a salicide layer formed within the amorphization implant in the first semiconductor region.

27. A system, comprising:
a semiconductor package having
a first semiconductor region,
a second semiconductor region joined to the first semiconductor region to form a semiconductor junction,
an isolation trench at least partially filled with an insulating material and disposed in a truncating relationship with the first and second semiconductor regions, with the semiconductor junction terminating at the isolation trench so as to define a junction end of the semiconductor junction, and
an amorphization implant being formed in the first semiconductor region and having a proximal and a distal implant end relative to the junction end of the semiconductor junction, the proximal implant end being disposed in spaced-relationship to the junction end; and
a bus coupled to the semiconductor package; and
a network interface module coupled to the bus.

28. The system according to claim 27, wherein the semiconductor package further comprises
a boundary defined between the isolation trench and the first and second semiconductor regions, with the junction end of the semiconductor junction terminating at the boundary; and
a salicide-blocking barrier formed on a first portion of the first semiconductor region located adjacent to the boundary.

29. The system according to claim 28, wherein the salicide-blocking barrier of the semiconductor package extends at least from the boundary to the proximal implant end.

30. The system according to claim 28, wherein the salicide-blocking barrier of the semiconductor package is formed on at least a portion of the insulating material adjacent to the boundary.
